(19) United States
(12) Patent Application Publication
(10) Pub. No.: US 2011/0151613 A1
(43) Pub. Date: Jun. 23, 2011

(54) Solid-state image capturing element, method for manufacturing the solid-state image capturing element, and electronic information device

(75) Inventors: Kenichi Nagai, Hiroshima (JP); Noboru Takeuchi, Mie (JP); Kazuo Ohtsubo, Hiroshima (JP); Yuhji Hara, Hiroshima (JP)

(73) Assignee: Sharp Kabushiki Kaisha, Osaka (JP)

(21) Appl. No.: 12/932,297

(22) Filed: Feb. 22, 2011

Related U.S. Application Data
(62) Division of application No. 12/318,990, filed on Jan. 14, 2009.

(30) Foreign Application Priority Data
Jan. 18, 2008 (JP) 2008-009550

(51) Int. Cl. H01L 31/18

(52) U.S. Cl. 438/72; 257/E31.127

(57) ABSTRACT

A solid-state image capturing element according to the present invention is provided, in which one or a plurality of light receiving sections for photoelectrically converting an incident light to generate a signal charge is provided on a surface of a semiconductor area or a surface of a semiconductor substrate and a peripheral circuit with a transistor is provided, where a reflection preventing film provided above the light receiving sections and a gate sidewall film of the transistor are formed with a common nitride film that is formed simultaneously.

This nonprovisional application claims priority under 35 U.S.C. §119(a) to Patent Application No. 2008-009550 filed in Japan on Jan. 18, 2008, the entire contents of which are hereby incorporated by reference.

### BACKGROUND OF THE INVENTION

1. Field of the Invention

The present invention relates to a solid-state image capturing element configured with a semiconductor element for performing a photoelectric conversion on and capturing an image light from a subject, a method for manufacturing the solid-state image capturing element, and an electronic information device, such as a digital camera (e.g., a digital video camera and a digital still camera), an image input camera (e.g., a security camera and a car-mounted camera), a scanner, a facsimile machine, and a camera-equipped cell phone device, having the solid-state image capturing element as an image input device used in an image capturing section thereof.

2. Description of the Related Art

Reference 1 proposes a technique that, in a conventional solid-state image capturing element such as the one described above, a SiON film is used as a reflection preventing film for a reflection preventing technique of a photodiode in a pixel section of a CCD and MOS imager, and the percentage of constituent of oxygen and nitrogen is varied from a lower layer to an upper layer in forming the SiON film, thereby a refractive index of the film is gradually changed. As a result, compared to a conventional technique, incident light can be prevented from being reflected at a silicon surface and a surface of a silicon oxide film above the silicon surface to increase the amount of incident light entering a photodiode. Accordingly, a high sensitivity can be obtained at the photodiode.

In addition, as a conventional technique of Reference 1, it is disclosed that a laminated structure of a silicon oxide film and a silicon nitride film are formed above a photo diode so as to significantly control the reflection compared to previous techniques. In this case, a thin silicon oxide film is formed above a silicon substrate, the thin silicon oxide film functioning as a gate insulation film, and a silicon nitride film is formed above the thin silicon oxide film, the silicon nitride film functioning as a thin reflection preventing film and having a refraction index greater than that of the silicon oxide film and smaller than that of the silicon substrate. The silicon oxide film has a refraction index of about 1.45. The silicon nitride film has a refraction index of about 2.0. The silicon nitride film is set to be about 350/(4n)nm≦t≦450/(4n)nm, where t=film thickness and n=refractive index. The silicon oxide film and silicon nitride film are formed to prevent a dark current.

That is, the film thickness of the silicon nitride film can be set as an effective film thickness for preventing a reflection of 350/(4n)nm≦t≦450/(4n)nm. In this case, n is a refractive index of the silicon nitride film.

In addition, Reference 2 discloses a way to obtain a sufficiently fine color image by laminating a silicon oxide film, a polycrystalline silicon film and a silicon nitride film in this order on a semiconductor substrate to use a multiple interference effect and improve short wavelength sensitivity.
Reference 1: Japanese Laid-Open Publication No. 2003-229562
Reference 2: Japanese Laid-Open Publication No. 60-177778

### SUMMARY OF THE INVENTION

Both of the above-mentioned references describe the conventional structure where a silicon nitride film is formed as a reflection preventing film having the film thickness described above. However, in a case where a peripheral circuit of a pixel section is included, such as a CMOS solid-state image capturing element, a silicon nitride film, which is a reflection preventing film above a pixel section, is formed once, and subsequently and separately, a gate side wall for a transistor, which is the peripheral circuit, is formed in a step before or after the formation of the silicon nitride film. As a result, two silicon nitride films having a different film thickness are needed to be formed separately for the reflection preventing film and the gate side wall, thereby resulting in an increase of the steps of the formation of the film.

The present invention is intended to solve the conventional problems described above. The objective of the present invention is to provide a solid-state image capturing element, in which a reflection preventing film above a pixel section and a gate side wall film of a transistor, which is a peripheral circuit, are formed with a common silicon nitride film in order to simplify manufacturing steps; a method for manufacturing the solid-state image capturing element; and an electronic information device having the solid-state image capturing element used in an image capturing section thereof.

A solid-state image capturing element according to the present invention is provided, in which one or a plurality of light receiving sections for photoelectrically converting an incident light to generate a signal charge is provided on a surface of a semiconductor area or a surface of a semiconductor substrate and a peripheral circuit with a transistor is provided, wherein a reflection preventing film provided above the light receiving sections and a gate sidewall film of the transistor are formed with a common nitride film that is formed simultaneously, thereby achieving the objective described above.

Preferably, in a solid-state image capturing element according to the present invention, the reflection preventing film is configured of one layer of a silicon nitride film that is provided above the light receiving sections with a silicon oxide layer interposed therebetween.

Still preferably, in a solid-state image capturing element according to the present invention, the reflection preventing film is configured of two layers of a silicon nitride film that is provided above the light receiving sections with a silicon oxide layer interposed therebetween and a SiON film above the silicon nitride film.

Still preferably, in a solid-state image capturing element according to the present invention, the reflection preventing film is configured of two layers of a silicon nitride film having a low concentration of nitride that is provided above the light receiving sections with a silicon oxide film interposed therebetween and a silicon nitride film having a high concentration of nitride above the silicon nitride film having a low concentration of nitride.

Still preferably, in a solid-state image capturing element according to the present invention, the gate sidewall film is configured of the silicon nitride film.

Still preferably, in a solid-state image capturing element according to the present invention, the gate sidewall film is configured of two layers of the silicon nitride film and the SiON film.

Still preferably, in a solid-state image capturing element according to the present invention, the gate sidewall film is configured of two layers of the silicon nitride film having a low concentration of nitride and the silicon nitride film having a high concentration of nitride.

Still preferably, in a solid-state image capturing element according to the present invention, a film thickness of the reflection preventing film is set to be thinner than a film thickness necessary for obtaining a film thickness of the gate sidewall film.

Still preferably, in a solid-state image capturing element according to the present invention, the reflection preventing film is set to have a film thickness of t (nm) and to be in an effective film thickness range of 30 nm<t<150 nm for preventing a reflection.

Still preferably, in a solid-state image capturing element according to the present invention, the peripheral circuit is at least either of a peripheral circuit of the one or plurality of light receiving sections or a peripheral circuit of each of the light receiving sections.

Still preferably, in a solid-state image capturing element according to the present invention, the peripheral circuit includes an output transistor for voltage-converting, amplifying and outputting a signal charge that is transferred through a CCD charge transfer path.

A method for manufacturing a solid-state image capturing element according to the present invention, in which one or plurality of light receiving sections for photoelectrically converting an incident light to generate a signal charge is provided on a surface of a semiconductor area or a surface of a semiconductor substrate and a peripheral circuit with a transistor is provided, includes: a reflection preventing film and sidewall film forming step of forming a gate sidewall film of the transistor and a reflection preventing film provided above the light receiving sections in this order using a common nitride film that is formed simultaneously, thereby achieving the objective described above.

Preferably, in a method for manufacturing a solid-state image capturing element according to the present invention, the reflection preventing film and sidewall film forming step includes: a nitride film forming step of forming a nitride film above an area of the one or plurality of light receiving sections and the peripheral circuit; a sidewall film forming step of forming a gate sidewall film of a transistor of the peripheral circuit, by masking the one or plurality of light receiving sections or each of the plurality of light receiving sections; and a reflection preventing film forming step of forming the nitride film into a predetermined thickness as the reflection preventing film, by using a mask with an opening only above the light receiving section.

Still preferably, in a method for manufacturing a solid-state image capturing element according to the present invention, the reflection preventing film and sidewall film forming step includes: a first nitride film forming step of forming a first nitride film above an area of the one or plurality of light receiving sections and the peripheral circuit; a first sidewall film forming step of forming a first gate sidewall film of a transistor of the peripheral circuit, by masking the one or plurality of light receiving sections or each of the plurality of light receiving sections; a second nitride film forming step of forming a second nitride film above the area of the one or plurality of light receiving sections and the peripheral circuit; a second sidewall film forming step of forming a second gate sidewall film of the transistor of the peripheral circuit above the first gate sidewall film from the second nitride film, by masking the one or plurality of light receiving sections or each of the plurality of light receiving sections; and a reflection preventing film forming step of forming the first nitride film and the second nitride film into a predetermined thickness as the reflection preventing film, by using a mask with an opening only above the light receiving section.

Still preferably, in a method for manufacturing a solid-state image capturing element according to the present invention, the reflection preventing film and sidewall film forming step includes: a first nitride film forming step of forming a first nitride film above an area of the one or plurality of light receiving sections and the peripheral circuit; a second nitride film forming step of forming a second nitride film above the first nitride film; a sidewall film forming step of forming a gate sidewall film of a transistor of the peripheral circuit from the first nitride film and the second nitride film, by masking the one or plurality of light receiving sections or each of the plurality of light receiving sections; and a reflection preventing film forming step of forming the first nitride film and the second nitride film into a predetermined thickness as the reflection preventing film, by using a mask with an opening only above the light receiving section.

Still preferably, in a method for manufacturing a solid-state image capturing element according to the present invention, the reflection preventing film is one layer of a silicon nitride film that is provided above the light receiving sections with a silicon oxide layer interposed therebetween.

Still preferably, in a method for manufacturing a solid-state image capturing element according to the present invention, the reflection preventing film has a two layered structure of a silicon nitride film functioning as the first nitride film provided above the light receiving sections with a silicon oxide layer interposed therebetween and a SiON film above the silicon nitride film functioning as the second nitride film.

Still preferably, in a method for manufacturing a solid-state image capturing element according to the present invention, the reflection preventing film has a two layered structure of a silicon nitride film having a low concentration of nitride, which functions as the first nitride film provided above the light receiving sections with a silicon oxide layer interposed therebetween, and a silicon nitride film having a high concentration of nitride, which functions as the second nitride film, above the silicon nitride film having a low concentration of nitride.

Still preferably, in a method for manufacturing a solid-state image capturing element according to the present invention, the reflection preventing film and the sidewall film are respectively formed by an etching process.

An electronic information device according to the present invention has the solid-state image capturing element according to the present invention used in an image capturing section.

The functions of the present invention having the structures described above will be described hereinafter.

According to the present invention, a reflection preventing film provided above a light receiving section and a gate side wall film of a transistor, which is a peripheral circuit of the light receiving section, are formed by a common nitride film that is formed simultaneously. Therefore, a silicon nitride film, which has a film thickness of the thick gate side wall film, is formed first, and subsequently, the reflection preventing film with a desired film thickness is formed only above a pixel section (light receiving section) using a mask with an opening above the pixel section (light receiving section). As described above, the formation of the common silicon nitride film is completed in one step even if the thickness of the film of the gate side wall film and the reflection preventing film is different from each other, thereby simplifying the manufacturing steps compared to the conventional two steps.

The silicon nitride film is conventionally formed in two steps in the conventional semiconductor apparatus having both a light receiving section and a peripheral circuit, such as a CMOS solid-state image capturing element, because the necessary film thickness is different for a silicon nitride film that functions as a reflection preventing film above a light receiving section and a silicon nitride film that is used as a gate side wall film for a peripheral circuit of the light receiving section. On the other hand, according to the present invention as described above, the reflection preventing film provided above the light receiving section and the gate sidewall film of a peripheral circuit of the light receiving section are formed with a common silicon nitride film that is formed simultaneously, so that one step of forming the silicon nitride film forms both of the reflection preventing film and the gate sidewall film, thereby simplifying the manufacturing steps.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view of a pixel section and its peripheral circuit, illustrating a silicon nitride film forming step in a method for manufacturing a solid-state image capturing element according to Embodiment 1 of the present invention.

FIG. 2 is a longitudinal cross sectional view of a pixel section and its peripheral circuit, illustrating a gate sidewall film forming step in a method for manufacturing a solid-state image capturing element according to Embodiment 1 of the present invention.

FIG. 3 is a longitudinal cross sectional view of a pixel section and its peripheral circuit, illustrating a reflection preventing film forming step in a method for manufacturing a solid-state image capturing element according to Embodiment 1 of the present invention.

FIG. 4 is a longitudinal cross sectional view of a pixel section and its peripheral circuit, illustrating a resist film removing step subsequent to a reflection preventing film forming step in a method for manufacturing a solid-state image capturing element according to Embodiment 1 of the present invention.

FIG. 5 is a longitudinal cross sectional view of a pixel section and its peripheral circuit, illustrating a nitride film forming step in a method for manufacturing a solid-state image capturing element according to Embodiment 2 of the present invention.

FIG. 6 is a longitudinal cross sectional view of a pixel section and its peripheral circuit, illustrating a gate sidewall film forming step in a method for manufacturing a solid-state image capturing element according to Embodiment 2 of the present invention.

FIG. 7 is a longitudinal cross sectional view of a pixel section and its peripheral circuit, illustrating a reflection preventing film forming step in a method for manufacturing a solid-state image capturing element according to Embodiment 2 of the present invention.

FIG. 8 is a longitudinal cross sectional view of a pixel section and its peripheral circuit, illustrating a resist film removing step subsequent to a reflection preventing film forming step in a method for manufacturing a solid-state image capturing element according to Embodiment 2 of the present invention.

FIG. 9 is a longitudinal cross sectional view of a pixel section and its peripheral circuit, illustrating a silicon nitride film forming step in a method for manufacturing a solid-state image capturing element according to Embodiment 3 of the present invention.

FIG. 10 is a longitudinal cross sectional view of a pixel section and its peripheral circuit, illustrating a gate sidewall film forming step in a method for manufacturing a solid-state image capturing element according to Embodiment 3 of the present invention.

FIG. 11 is a longitudinal cross sectional view of a pixel section and its peripheral circuit, illustrating a reflection preventing film forming step in a method for manufacturing a solid-state image capturing element according to Embodiment 3 of the present invention.

FIG. 12 is a longitudinal cross sectional view of a pixel section and its peripheral circuit, illustrating a resist film removing step subsequent to a reflection preventing film forming step in a method for manufacturing a solid-state image capturing element according to Embodiment 3 of the present invention.

FIG. 13 is a block diagram illustrating an exemplary diagrammatic structure of an electronic information device of Embodiment 5 of the present invention, having a solid-state image capturing apparatus including the solid-state image capturing element according to any of Embodiments 1 to 4 of the present invention used in an image capturing section thereof.

1, 11, 21 semiconductor substrate
2, 12, 22 gate oxide film
3, 13, 23 gate polysilicon
4, 4a, 14, 142a silicon nitride film
14a, 142b SiON film
24, 242a silicon nitride film having a low concentration of nitride
24a, 242b silicon nitride film having a high concentration of nitride
41, 141a, 141b, 241a, 241b gate sidewall film
42, 142, 242 reflection preventing film
5, 15, 25, 6, 16, 26 resist film
10, 20, 30, 40 solid-state image capturing element
90 electronic information device
91 solid-state image capturing apparatus
92 memory section
93 display section
94 communication section
95 image output section

### DESCRIPTION OF THE PREFERRED EMBODIMENTS

Hereinafter, a solid-state image capturing element according to the present invention and a method for manufacturing the solid-state image capturing element will be described in Embodiments 1 to 4, and an electronic information device using the solid-state image capturing element according to the present invention and the method for manufacturing the solid-state image capturing element in Embodiments 1 to 4 will be described in Embodiment 5 with reference to accompanying figures.

### Embodiment 1

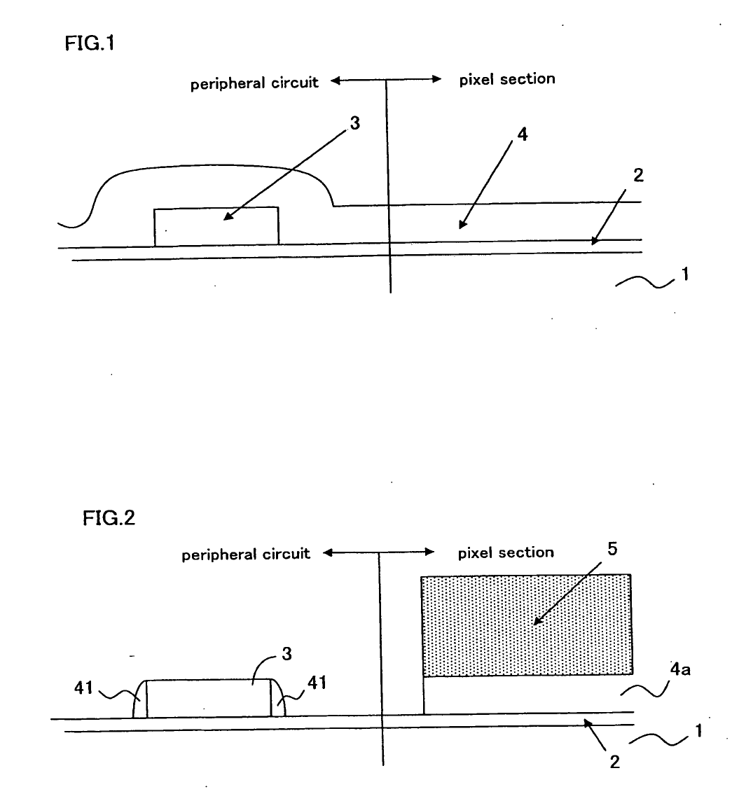

A solid-state image capturing element according to Embodiment 1 includes one or a plurality of light receiving sections for performing a photoelectric conversion on an incident light to generate a signal charge, provided on a surface of a semiconductor or a surface of a semiconductor substrate. In addition, a peripheral circuit is provided in a periphery of the one or plurality of light receiving sections or in a periphery of each light receiving section. A characteristic structure of the solid-state image capturing element according to Embodiment 1 is that a reflection preventing film provided above each light receiving section and a gate sidewall film of a transistor, which is a peripheral circuit of the light receiving section, are formed with a common silicon nitride film that is formed simultaneously when each light receiving section and its peripheral circuit are simultaneously manufactured. The gate sidewall film sets the distance between a source and a drain so that the transistor reliably performs an on and off operation and a certain current flows into the transistor. A method for manufacturing the solid-state image capturing element of Embodiment 1 will be described with reference to FIGS. 1 to 4, where a transistor sidewall film, which requires a thick silicon nitride film, is first formed, and subsequently, the silicon nitride film is thinned to be a thin silicon nitride film that is suitable for preventing a reflection.

FIG. 1 is a longitudinal cross sectional view of a pixel section and its peripheral circuit, illustrating a silicon nitride film forming step in a method for manufacturing the solid-state image capturing element according to Embodiment 1 of the present invention.

As illustrated in a nitride film forming step in FIG. 1, a plurality of light receiving sections are formed in an image capturing area (pixel section) in a two dimensional matrix. In addition, on an entire surface of a semiconductor substrate 1 or a semiconductor area, a gate oxide film 2, which is a silicon oxide film, is formed. Provided on the semiconductor substrate 1 or the semiconductor area are a peripheral circuit, such as a signal reading circuit formed in the periphery of each light receiving section and a driver circuit for driving the peripheral circuit for each light receiving section provided in an image capturing area (a plurality of light receiving sections). A gate polysilicon 3 of the transistor, or the peripheral circuit, is provided at an appropriate location above the gate oxide film 2. A silicon nitride film 4 is formed above the gate polysilicon 3 and the gate oxide film 2, namely above an area of the plurality of light receiving sections and the peripheral circuit. The silicon nitride film 4 turns to be a gate sidewall film 41 and a reflection preventing film 42, which will be discussed later, subsequent to the formation of the gate polysilicon 3 of each transistor of the peripheral circuit. The film thickness of the silicon nitride film 4 at this stage is set to be a film thickness necessary for forming the gate sidewall film.

Herein, the formation of the silicon nitride film 4 may be by a low pressure CVD or by using a diffusion furnace. The thickness of the silicon nitride film 4 is formed to be in a range of 50 to 200 nm so that a gate sidewall width A (thickness) of the gate sidewall film 41 will be in a range of 30 to 120 nm.

FIG. 2 is a longitudinal cross sectional view of a pixel section and its peripheral circuit, illustrating a gate sidewall film forming step in a method for manufacturing the solid-state image capturing element according to Embodiment 1 of the present invention.

As illustrated in the gate sidewall film forming step in FIG. 2, a plurality of light receiving sections or each light receiving section is masked by a resist film 5 to form the gate sidewall film 41 of the transistor, or the peripheral circuit. That is, a silicon nitride film 4a of the plurality of light receiving sections formed in the image capturing area (pixel section) is masked by a resist film 5 and an opening is formed above the peripheral circuit. Further, the silicon nitride film 4 is removed by etching during the etching time and the amount of the etching (film thickness) is controlled to form the gate sidewall film 41 of the transistor at a predetermined width (predetermined thickness).

In this case, the etching is dry etching and the etching condition includes a pressure of 20 to 200 mTorr; a temperature of 25 to 100 degrees centigrade; power of 100 to 800 W; a type of gas of C₄F₈/O₂/Ar or CF₄/CHF₃/O₂/Ar; and a flow rate of 5 to 50 sccm for the above described C₄F₈, CF₄, CHF₃, and O₂, and 100 to 500 sccm for Ar.

Herein, the gate sidewall width A (thickness) of the gate sidewall film 41 is approximately 60 percent of the film thickness even though it depends on a thickness of a poly film. For example, the gate sidewall width A (thickness) of the gate sidewall film 41 becomes 60 nm when the silicon nitride film 4 is formed with the thickness of 100 nm.

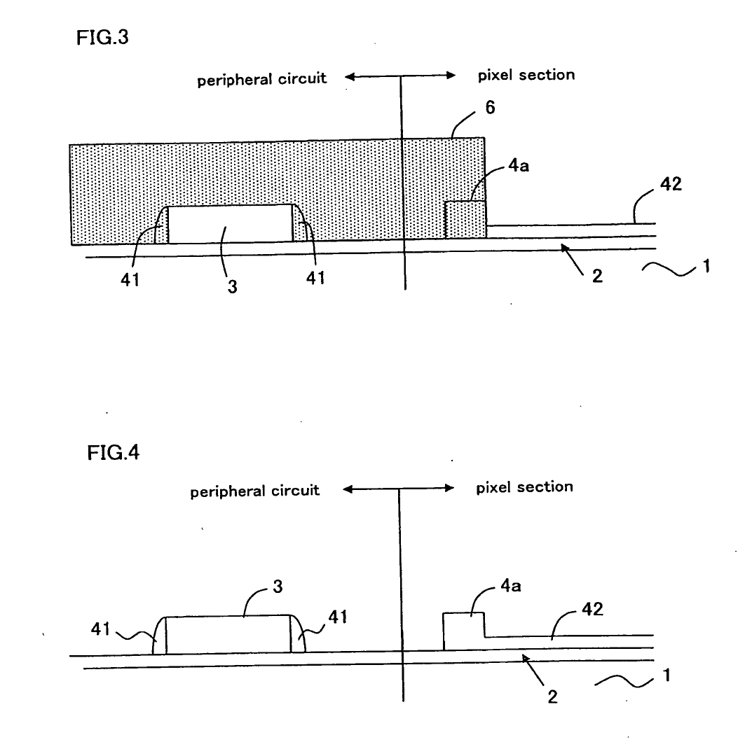

FIG. 3 is a longitudinal cross sectional view of a pixel section and its peripheral circuit, illustrating a reflection preventing film forming step in a method for manufacturing the solid-state image capturing element according to Embodiment 1 of the present invention.

As illustrated in the reflection preventing film forming step in FIG. 3, the silicon nitride film 4 is formed into a predetermined film thickness as a reflection preventing film 42, using a resist film 6 with an opening only above each light receiving section. That is, the peripheral circuit side is masked by the resist film 6 and the etching time is controlled for etching the silicon nitride film 4 to form a reflection preventing film 42 having a desired film thickness is formed for controlling a reflection. In addition, considering an alignment accuracy of the resist film 6, the peripheral circuit side is masked by the resist film 6 in such a manner to include an end portion of the silicon nitride film 4.

In this case, dry etching is used as well, and the etching condition includes a pressure of 20 to 200 mTorr; a temperature of 25 to 100 degrees centigrade; power of 100 to 800 W; a type of gas of C₄F₈/O₂/Ar or CF₄/CHF₃/O₂/Ar; and a flow rate of 5 to 50 sccm for the above described C₄F₈, CF₄, CHF₃, and O₂, and 100 to 500 sccm for Ar. However, a wet etching may be used instead of the dry etching in this case.

Subsequently, the resist film 6 is removed as illustrated in FIG. 4. By doing so, the reflection preventing film 42 and the gate sidewall film 41 of the transistor, or the peripheral circuit, are formed with the silicon nitride film 4 as a film of a common material, thereby simplifying the manufacturing steps. As a result, the solid-state image capturing element according to Embodiment 1 is manufactured.

In this case, the film thickness t (nm) of the reflection preventing film 42 with the silicon nitride film 4 as the material of the film can be set in a reflection preventing effective range of 350/(4n) nm<t<450/(4n) nm, where n is a refractive index of the silicon nitride film. That is, the reflection preventing film 42 with the silicon nitride film 4 as the material of the film has a film thickness of t (nm) and is set in an effective film thickness range of 30 nm<t<150 nm for preventing a reflection.

As described above, the method for manufacturing the solid-state image capturing element according to Embodiment 1 includes a reflection preventing film and a sidewall film forming step for forming the gate sidewall film 41 of the transistor and the reflection preventing film 42 provided above the light receiving section in this order using the common silicon nitride film that is formed simultaneously.

The solid-state image capturing element according to Embodiment 1 includes the thin silicon oxide film (e.g., gate oxide film) above a pixel section; and a silicon nitride film thereabove, which will be the reflection preventing film 42. The silicon nitride film (SiN film) also functions as the gate sidewall film 41 of a gate section of the transistor, which configures various circuits formed in the periphery of the pixel section.

According to Embodiment 1 described above, the reflection preventing film 42 provided above the light receiving section and the gate sidewall film 41 of the transistor, or the peripheral circuit, of the light receiving section are formed with the common silicon nitride film 4 that is simultaneously formed, so that the silicon nitride film of the thickness of the thick gate sidewall film 41 is first formed, and subsequently, the reflection preventing film 42 is formed using the mask with an opening above the pixel section in such a manner to form the previously-mentioned reflection preventing effective film thickness. As a result, the formation of the silicon nitride film 4 is completed in one step. Compared with the conventional technique, where the formation of the reflection preventing film and the formation of the gate sidewall, which is used as a barrier for an ion plantation, are performed separately in two steps, the manufacturing steps can be simplified.

### Embodiment 2

In Embodiment 1 described above, one layer of a silicon nitride film (SiN film) is formed as a reflection preventing film above the gate oxide film 2. In Embodiment 2, a two layered structure of a silicon nitride film (SiN film) and a SiON film thereabove are formed as a reflection preventing film above the gate oxide film 2. When the SiON film is laminated above the silicon nitride film as described above, a reflection can be controlled in a more effective manner.

FIG. 5 is a longitudinal cross sectional view of a pixel section and its peripheral circuit, illustrating a nitride film forming step in a method for manufacturing the solid-state image capturing element according to Embodiment 2 of the present invention.

As illustrated in the nitride film forming step in FIG. 5, a plurality of light receiving sections are formed in an image capturing area (pixel section) in a two dimensional matrix. In addition, a gate oxide film 12 is formed above an entire surface of a semiconductor substrate 11. Provided on the semiconductor substrate 11 are peripheral circuits, such as a signal reading circuit (including an amplifying transistor and a reset transistor) formed in the periphery of each light receiving section and a driver circuit (including a plurality of transistors) for driving the peripheral circuit for each light receiving section provided in an image capturing area (pixel section). A gate polysilicon 13 of the transistor, or the peripheral circuit, is provided at an appropriate location above the gate oxide film 12. A silicon nitride film 14 (SiN film) is formed with a predetermined film thickness above the gate polysilicon 13 and the gate oxide film 12, namely above an area of the plurality of light receiving sections and the peripheral circuit. The silicon nitride film 14 turns to be a gate sidewall film 141a and a silicon nitride film 142a (SiN film) of a reflection preventing film, which will be discussed later, subsequent to the formation of the gate polysilicon 13 of each transistor of the peripheral circuit. The film thickness of the silicon nitride film 14 (SiN film) at this stage is set to be a film thickness necessary for forming the gate sidewall film.

Herein, the formation of the silicon nitride film 14 may be by a low pressure CVD or by using a diffusion furnace. The thickness of the silicon nitride film 14 is formed to be substantially half of 50 to 200 nm (25 to 100 nm in thickness) so that a gate sidewall width A′ of the gate sidewall film 141a will be substantially half of 30 to 120 nm (15 to 60 nm in width).

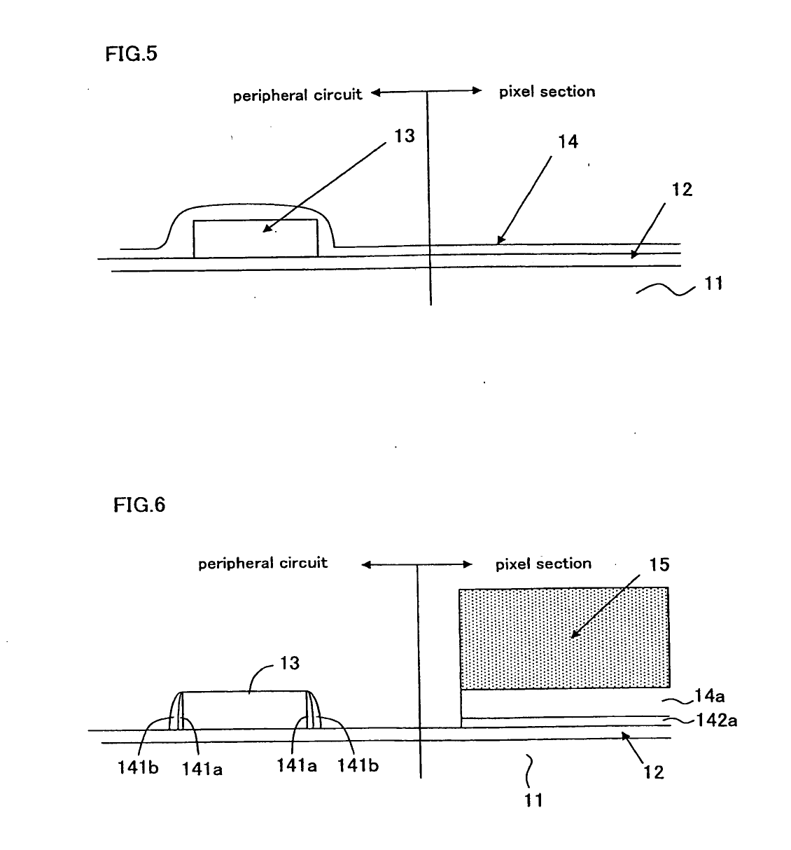

FIG. 6 is a longitudinal cross sectional view of a pixel section and its peripheral circuit, illustrating a gate sidewall film forming step in a method for manufacturing the solid-state image capturing element according to Embodiment 2 of the present invention.

In the gate sidewall film forming step in FIG. 6, a silicon nitride film 142a (SiN film) on a plurality of light receiving sections or each light receiving section is masked by a resist film 15 to form the gate sidewall film 141a of the transistor, or the peripheral circuit. That is, a silicon nitride film 142a of the plurality of light receiving sections formed in the image capturing area (pixel section) is masked by a resist film 15 and an opening is formed above the peripheral circuit. Further, the silicon nitride film 14 (SiN film) is removed by etching to form the gate sidewall film 141a of the transistor.

In this case, the etching is dry etching and the etching condition includes a pressure of 20 to 200 mTorr; a temperature of 25 to 100 degrees centigrade; power of 100 to 800 W; a type of gas of C₄F₈/O₂/Ar or CF₄/CHF₃/O₂/Ar; and a flow rate of 5 to 50 sccm for the above described C₄F₈, CF₄, CHF₃, and O₂, and 100 to 500 sccm for Ar.

Herein, the gate sidewall width A′ (thickness) of the gate sidewall film 141a is approximately 60 percent of the film thickness even though it depends on a thickness of a poly film.

Similarly, a predetermined thickness of a SiON film is formed on the SiN film above the area of the plurality of light receiving sections and the peripheral circuit. The SiON film 14a above the plurality of light receiving sections or each light receiving section is masked by a similar resist film 15 to form a gate sidewall film 141b of a transistor of a peripheral circuit section. As a result, the sum of the gate sidewall width A′ (thickness) of the gate sidewall film 141a and a gate sidewall width A″ (thickness) of the gate sidewall film 141b becomes the gate sidewall width A. Herein, the gate sidewall width A′ and the gate sidewall width A″ are equal.

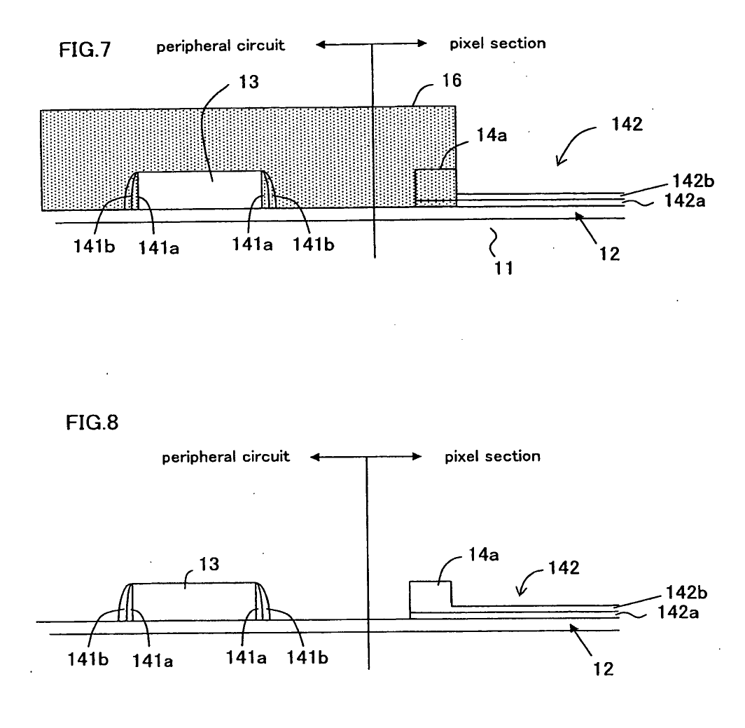

FIG. 7 is a longitudinal cross sectional view of a pixel section and its peripheral circuit, illustrating a reflection preventing film forming step in a method for manufacturing the solid-state image capturing element according to Embodiment 2 of the present invention.

As illustrated in the reflection preventing film forming step in FIG. 7, a predetermined thickness of a two layered structure of a silicon nitride film 142a (SiN film) and a SiON film 142b thereabove are formed as a reflection preventing film 142, using a resist film 16 with an opening only above the light receiving section. That is, the peripheral circuit section side is masked by the resist film 16 and the SiON film 142b is etched with a time control in order to form the reflection preventing film 142 for controlling a reflection having a desired film thickness. In FIG. 7, the film thickness of the SiON film 142b after the etching and the thickness of the silicon nitride film 142a (SiN film) are illustrated with the same film thickness for simplicity; however, the film thickness of the SiON film 142b is actually thinned by the etching for the amount that it is etched.

In this case, dry etching is used as well, and the etching condition includes a pressure of 20 to 200 mTorr; a temperature of 25 to 100 degrees centigrade; power of 100 to 800 W; a type of gas of C₄F₈/O₂/Ar or CF₄/CHF₃/O₂/Ar; and a flow rate of 5 to 50 sccm for the above described C₄F₈, CF₄, CHF₃, and O₂, and 100 to 500 sccm for Ar. However, a wet etching may be used instead of the dry etching in this case.

Subsequently, the resist film 16 is removed as illustrated in FIG. 8. By doing so, two layers of the reflection preventing film 142 and the gate sidewall films 141a and 141b of the transistor, or the peripheral circuit, are formed with the silicon nitride film 14 and the SiON film as a film of a common material, thereby simplifying the manufacturing steps. As a result, the solid-state image capturing element according to Embodiment 2 is manufactured.

In this case, the total film thickness t (nm) of the reflection preventing film 142, which has the two layered films of the silicon nitride film 14 and the SiON film as the material of the film, is the total sum of respective films and can be set within a predetermined range that is effective for preventing the reflection.

The solid-state image capturing element according to Embodiment 2 includes a thin, a silicon oxide film (e.g., gate oxide film 2) above a pixel section; a silicon nitride film 142a (SiN film) for functioning as a reflection preventing film provided above the silicon oxide film; and a SiON film 142b for functioning as a reflection preventing film further above the silicon nitride film 142a. The two layers of the silicon nitride film 142a (SiN film) and the SiON film 142b also function as the sidewall films 141a and 141b of the gate section of the transistor that configures various circuits formed in the periphery.

According to Embodiment 2 as described above, the reflection preventing film 142 and the gate sidewall films 141a and 141b of the transistor, or the peripheral circuit, of the light receiving section are formed with the two layered film of the common silicon nitride film 14 (SiN film) and the SiON film that are formed simultaneously, the reflection preventing film 142 being formed of a two layered film of the silicon nitride film 142a (SiN film) and the SiON film 142b, which are provided above the light receiving section with the silicon oxide film 2 interposed therebetween. The two layered film of the silicon nitride film 14 (SiN film), which is the total film thickness of the thick gate sidewall films 141a and 141b, and the SiON film are respectively formed first, and subsequent to each of the preceding formations, they are formed to be each constituent film of the reflection preventing film 142 with a desired film thickness, using a mask having an opening only above the pixel section. As a result, the formation of the two layered film of the nitride film (SiN film) and the SiON film is completed in one step. Compared with the conventional technique, where the formation of the reflection preventing film and the formation of the gate sidewall, which is used as a barrier for an ion plantation, are performed separately in two steps, the manufacturing steps can be simplified. Further, the two layered film of the nitride film (SiN film) and the SiON film is consecutively formed, and therefore, the gate sidewall films can be formed at once, and subsequently, the reflection preventing film 142 can be formed with a desired film thickness. In this case, the manufacturing steps can be further simplified. In addition, the gate side wall films can be formed with two different kinds of thickness when the reflection preventing film has a two layered structure.

### Embodiment 3

In Embodiment 1 described above, one layer of a silicon nitride film (SiN film) is formed as a reflection preventing film above the silicon oxide film 2. In Embodiment 3, a two layered structure of a silicon nitride film (SiN film) having a low concentration of nitride and a silicon nitride film thereabove having a high concentration of nitride (SiN film) are formed as a reflection preventing film above the silicon oxide film 2. It is thought that the refraction index increases as the concentration of nitride increases. Thus, when a high concentrated silicon nitride film (SiN film) is laminated above a low concentrated silicon nitride film (SiN film), a reflection can be more effectively controlled as similar to the case in Embodiment 2 described above.

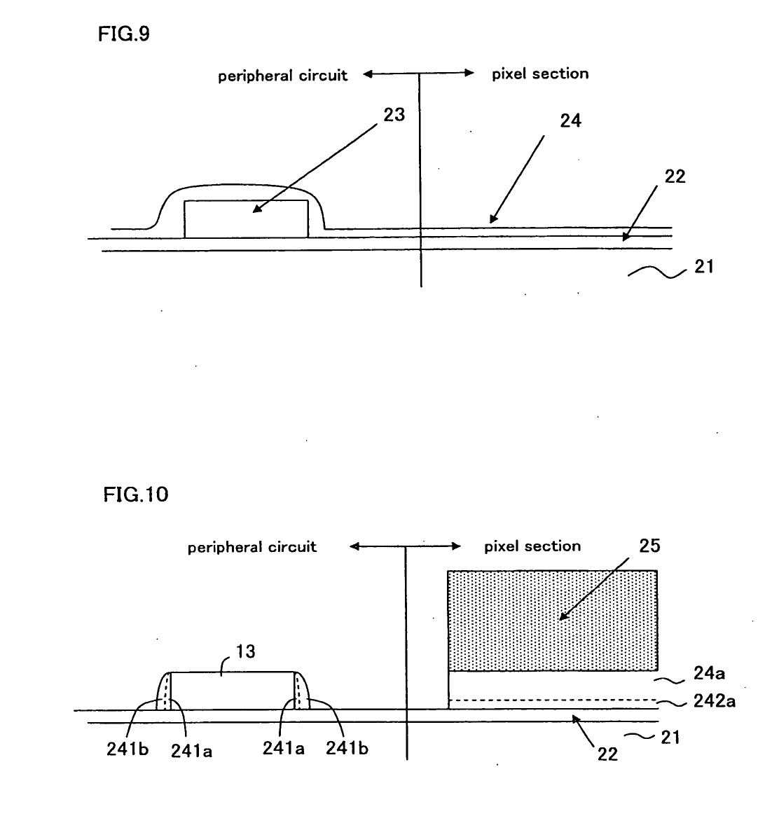

FIG. 9 is a longitudinal cross sectional view of a pixel section and its peripheral circuit, illustrating a silicon nitride film forming step in a method for manufacturing the solid-state image capturing element according to Embodiment 3 of the present invention.

As illustrated in the silicon nitride film forming step in FIG. 9, a plurality of light receiving sections are formed in an image capturing area (pixel section) in a two dimensional matrix. In addition, a gate oxide film 22 is formed above an entire surface of a semiconductor substrate 21. Provided on the semiconductor substrate 21 are peripheral circuits, such as a signal reading circuit (including an amplifying transistor and a reset transistor) formed in the periphery of each light receiving section and a driver circuit (including a plurality of transistors) for driving the peripheral circuit for each light receiving section provided in an image capturing area (pixel section). A gate polysilicon 23 of the transistor, or the peripheral circuit, is provided at an appropriate location above the gate oxide film 22. A silicon nitride film 24 (SiN film) having a low concentration of nitride is formed with a predetermined film thickness above the gate polysilicon 23 and the gate oxide film 22, namely above an area of the plurality of light receiving sections and the peripheral circuit. The silicon nitride film 24 having a low concentration of nitride turns to be a gate sidewall film 241a and a silicon nitride film 242a (SiN film) having a low concentration of nitride of a reflection preventing film, which will be discussed later, subsequent to the formation of the gate polysilicon 23 of each transistor of the peripheral circuit. The film thickness of the silicon nitride film 24 (SiN film) at this stage is set to be a film thickness necessary for forming the gate sidewall film.

Herein, the formation of the silicon nitride film 24 having a low concentration of nitride may be by a low pressure CVD or by using a diffusion furnace. The thickness of the silicon nitride film 24 is formed to be substantially half of 50 to 200 nm (25 to 100 nm in thickness) so that a gate sidewall width A′ of the gate sidewall film 241a will be substantially half of 30 to 120 nm (15 to 60 nm in width).

FIG. 10 is a longitudinal cross sectional view of a pixel section and its peripheral circuit, illustrating a gate sidewall film forming step in a method for manufacturing the solid-state image capturing element according to Embodiment 3 of the present invention.

As illustrated in the gate sidewall film forming step in FIG. 10, a silicon nitride film 24a (SiN film) having a low concentration of nitride on a plurality of light receiving sections or each light receiving section is masked by a resist film 25 to form a gate sidewall film 241a of the transistor, or the peripheral circuit. That is, a silicon nitride film 24a of the plurality of light receiving sections formed in the image capturing area (pixel section) is masked by a resist film 25 and an opening is formed above the peripheral circuit. Further, the silicon nitride film 24 (SiN film) having a low concentration of nitride is removed by etching to form the gate sidewall film 241a of the transistor.

In this case, the etching is dry etching and the etching condition includes a pressure of 20 to 200 mTorr; a temperature of 25 to 100 degrees centigrade; power of 100 to 800 W; a type of gas of C₄F₈/O₂/Ar or CF₄/CHF₃/O₂/Ar; and a flow rate of 5 to 50 sccm for the above described C₄F₈, CF₄, CHF₃, and O₂, and 100 to 500 sccm for Ar.

Herein, the gate sidewall width A′ (thickness) of the gate sidewall film 241a is approximately 60 percent of the film thickness even though it depends on a thickness of a poly film.

Similarly, a predetermined thickness of a SiON film having a high concentration of nitride is formed on the SiN film 242a having a low concentration of nitride above the area of the plurality of light receiving sections and the peripheral circuit. The SiN film 242a having a low concentration of nitride above the plurality of light receiving sections or each light receiving section is masked by a similar resist film 25 to form a gate sidewall film 241b of a transistor of a peripheral circuit section. As a result, the sum of the gate sidewall width A′ (thickness) of the gate sidewall film 241a and a gate sidewall width A″ (thickness) of the gate sidewall film 241b becomes the gate sidewall width A. Herein, the gate sidewall width A′ and the gate sidewall width A″ are illustrated equally.

FIG. 11 is a longitudinal cross sectional view of a pixel section and its peripheral circuit, illustrating a reflection preventing film forming step in a method for manufacturing the solid-state image capturing element according to Embodiment 3 of the present invention.

As illustrated in the reflection preventing film forming step in FIG. 11, a predetermined thickness of a two layered structure of a silicon nitride film 242a (SiN film having a low concentration) having a low concentration of nitride and a silicon nitride film 242b (SiN film having a high concentration) having a high concentration of nitride are formed as a reflection preventing film 242, using a resist film 26 with an opening only above the light receiving section. That is, the peripheral circuit section side is masked by the resist film 26 and the SiON film 242b (SiN film having a high concentration) is etched with a time control in order to form the reflection preventing film 242 for controlling a reflection having a desired film thickness.

In this case, dry etching is used as well, and the etching condition includes a pressure of 20 to 200 mTorr; a temperature of 25 to 100 degrees centigrade; power of 100 to 800 W; a type of gas of C₄F₈/O₂/Ar or CF₄/CHF₃/O₂/Ar; and a flow rate of 5 to 50 sccm for the above described C₄F₈, CF₄, CHF₃, and O₂, and 100 to 500 sccm for Ar. However, a wet etching may be used instead of the dry etching in this case.

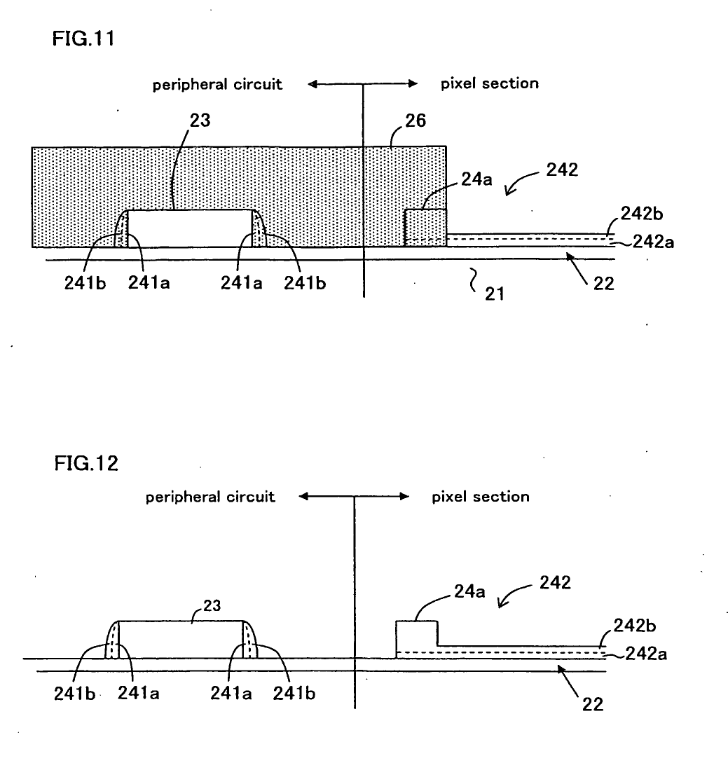

Subsequently, the resist film 26 is removed as illustrated in FIG. 12. By doing so, two layers of the reflection preventing film 242 and the gate sidewall films 241a and 241b of the transistor, or the peripheral circuit, are formed with the silicon nitride film 24 having a low concentration and the silicon nitride film having a high concentration as a film of a common material, thereby simplifying the manufacturing steps. As a result, the solid-state image capturing element according to Embodiment 3 is manufactured.

In this case, the total film thickness t (nm) of the reflection preventing film 242, which has the two layered films of the silicon nitride film 24 having a low concentration and the silicon nitride film having a high concentration as the material of the film, is the total sum of respective films and can be set within a predetermined range that is effective for preventing the reflection.

The solid-state image capturing element according to Embodiment 3 includes a thin, a silicon oxide film (e.g., gate oxide film 22) above a pixel section; a silicon nitride film 242a (SiN film) having a low concentration for functioning as a reflection preventing film provided above the silicon oxide film; and a SiON film 242b having a high concentration for functioning as a reflection preventing film further above the silicon nitride film 242a. The two layers of the silicon nitride films (SiN film) having a low concentration and a high concentration also function as the sidewall films 241a and 141b of the gate section of the transistor that configures various circuits formed in the periphery.

According to Embodiment 3 as described above, the reflection preventing film 242 and the gate sidewall films 241a and 241b of the transistor, or the peripheral circuit, of the light receiving section are formed with the two layered film of the common silicon nitride films (SiN film) having a low concentration and a high concentration that are formed simultaneously, the reflection preventing film 242 being formed of a two layered film of the nitride film (SiN film) having a low concentration and a high concentration, which are provided above the light receiving section with the gate oxide film 22 interposed therebetween. The two layered film of the nitride films (SiN film) having a low concentration and a high concentration is respectively and individually formed first, which is the total film thickness of the thick gate sidewall films 141a and 141b. Subsequent to each of the preceding formations, the gate sidewall films 241a and 241b are formed to be each constituent film of the reflection preventing film 242 with a desired film thickness, using a mask having an opening only above the pixel section. As a result, the formation of the two layered film of the nitride film (SiN film) having a low concentration and a high concentration is completed in one step. Compared with the conventional technique, where the formation of the reflection preventing film and the formation of the gate sidewall, which is used as a barrier for an ion plantation, are performed separately in two steps, the manufacturing steps can be simplified. Further, the two layered film of the nitride film (SiN film) having a low concentration and a high concentration is consecutively formed and the gate sidewall films is formed, and subsequently, the reflection preventing film 242 can be formed with a desired film thickness.

The reflection preventing film and the sidewall film forming step in Embodiment 1 described above includes: a nitride film forming step of forming a silicon nitride film 4 above an area of one or plurality of light receiving sections and its peripheral circuit; a sidewall film forming step of forming a gate sidewall film 41 of a transistor of a peripheral circuit, by masking one or a plurality of light receiving sections or each of the plurality of light receiving sections; and a reflection preventing film forming step of forming a predetermined thickness of the silicon nitride film 4 as a reflection preventing film 42, using a mask with an opening only above the light receiving section. Without limitation to this, the reflection preventing film and the sidewall film forming step in Embodiments 2 and 3 described above may include: a first nitride film forming step of forming a first nitride film above an area of one or a plurality of light receiving sections and its peripheral circuit; a first sidewall film forming step of forming a first gate sidewall film of a transistor of a peripheral circuit, from the first nitride film, masking one or plurality of light receiving sections or each of the plurality of light receiving sections; a second nitride film forming step of forming a second nitride film above an area of one or plurality of light receiving sections and its peripheral circuit; a second sidewall forming step of forming a second gate sidewall film of the transistor, or the peripheral circuit, and a reflection preventing film forming step of forming the first nitride film and the second nitride film into a predetermined film thickness of a reflection preventing film, using a mask with an opening only above the light receiving section. Alternatively, the reflection preventing film and the sidewall film forming step in Embodiments 2 and 3 may include: a first nitride film forming step of forming a first nitride film above an area of one or plurality of light receiving sections and its peripheral circuit; a second nitride film forming step of forming a second nitride film above the first nitride film; a sidewall film forming step of forming a gate sidewall film of a transistor of a peripheral circuit section, from the first nitride film and the second nitride film, masking one or plurality of light receiving sections or each of the plurality of light receiving sections; and a reflection preventing film forming step of forming the first nitride film and the second nitride film into a predetermined film thickness of a reflection preventing film, using a mask with an opening only above the light receiving section.

### Embodiment 4

In Embodiments 1 to 3 described above, cases with a CMOS solid-state image capturing element have been described, and a peripheral circuit provided in the periphery of each light receiving section includes a readout circuit that includes a charge transferring transistor, a reset transistor and an amplifying transistor (may also include a selection transistor). In addition, a peripheral circuit provided in the periphery of the plurality of light receiving sections (image capturing area) includes a driver circuit for controlling the readout circuit. In Embodiment 4, a case with a CCD solid-state image capturing element will be described.

Embodiment 4 is the same as Embodiments 1 to 3 described above in that a reflection preventing film is provided for a light receiving section. What is different will be that a gate sidewall film is formed at a gate of a signal output transistor, where a signal charge from each light receiving section is read out and transferred vertically, and subsequently, the signal charge is transferred horizontally and is amplified in the signal output transistor of a charge detecting section (transistor of a peripheral circuit section) to be outputted as an image capturing signal. Thus, the present invention can be applied for a CCD solid-state image capturing element to establish Embodiment 4 of the present invention.

Herein, the characteristics of the CMOS solid-state image capturing element and the CCD solid-state image capturing element will be briefly described.

Unlike the CCD image sensor, the CMOS solid-state image capturing element does not use a CCD for transferring a signal charge from each light receiving section using a vertical transfer section and transferring the signal charge from the vertical transfer section in a horizontal direction using a horizontal transfer section. Instead, the CMOS image sensor reads out a signal charge from the light receiving section for each pixel using a selection control line, formed by an aluminum wiring like a memory device, and converts the signal charge into a voltage. Subsequently, the CMOS image sensor successively reads out an image capturing signal amplified in accordance with the converted voltage from a selected pixel. On the other hand, the CCD image sensor requires a plurality of positive and negative power supply voltages for driving a CCD, whereas the CMOS image sensor is capable of driving itself with a single power supply, which enables a low electric consumption and low voltage driving compared with the CCD image sensor. Further, because a unique CCD manufacturing process is used for manufacturing the CCD image sensor, it is difficult to apply a manufacturing process generally used for a CMOS circuit directly to the manufacturing method for the CCD image sensor. On the other hand, the CMOS image sensor uses a manufacturing process generally used for the CMOS circuit. Therefore, a logic circuit, an analog circuit and an analog-digital conversion circuit and the like can be simultaneously formed by the CMOS process that is frequently used for manufacturing a driver circuit for controlling a display, a driver circuit for controlling image capturing, a semiconductor memory such as DRAM, and a logic circuit. That is, it is easy to form a CMOS image sensor on the same semiconductor chip in which a semiconductor memory, a driver circuit for controlling a display, and a driver circuit for controlling image capturing are formed. In addition, with respect to the manufacturing for the CMOS image sensor, it is easy for the CMOS image sensor to share a production line with the semiconductor memory, the driver circuit for controlling a display, and the driver circuit for controlling image capturing.

### Embodiment 5

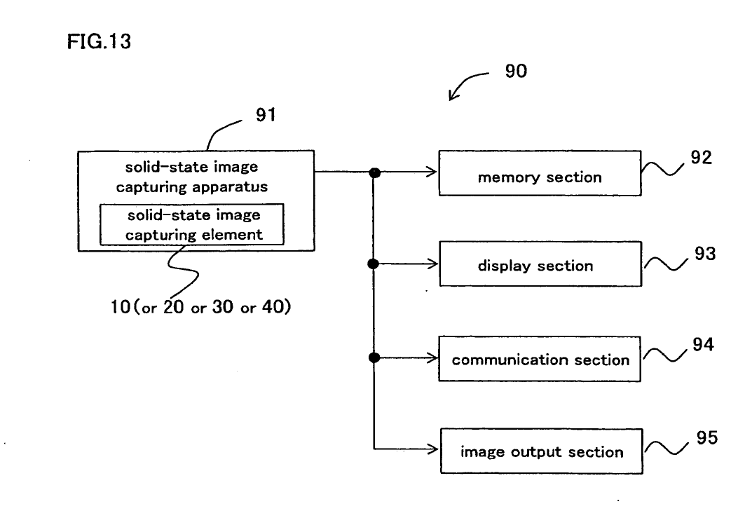

FIG. 13 is a block diagram illustrating an exemplary diagrammatic structure of an electronic information device of Embodiment 5 of the present invention, having a solid-state image capturing apparatus including the solid-state image capturing element according to any of Embodiments 1 to 4 of the present invention used in an image capturing section thereof.

In FIG. 13, the electronic information device 90 according to Embodiment 5 described above of the present invention includes: a solid-state image capturing apparatus 91 for performing various signal processing on an image capturing signal from any of the solid-state image capturing element 10 to Embodiment 1, the solid-state image capturing element 20 to Embodiment 2, the solid-state image capturing element 30 to Embodiment 3 and the solid-state image capturing element 40 to Embodiment 4, so as to obtain a color image signal; a memory section 92 (e.g., recording media) for data-recording a color image signal from the solid-state image capturing apparatus 91 after a predetermined signal process is performed on the color image signal for recording; a display section 93 (e.g., a color liquid crystal display apparatus) for displaying the color image signal from the solid-state image capturing apparatus 91 on a display screen (e.g., liquid crystal display screen) after predetermined signal processing is performed on the color image signal for display; a communication section 94 (e.g., a transmitting and receiving device) for communicating the color image signal from the solid-state image capturing apparatus 91 after predetermined signal processing is performed on the image signal for communication; and an image output section 95 for printing the color image signal from the solid-state image capturing apparatus 91 after predetermined signal processing is performed for printing. Without any limitations to this, the electronic information device 90 may include any of the memory section 92, the display section 93, the communication section 94, and the image output section 95 in addition to the solid-state image capturing apparatus 91.

As the electronic information device 90, an electronic information device that includes an image input device is conceivable, such as a digital camera (e.g., digital video camera and digital still camera), an image input camera (e.g., a monitoring camera, a door phone camera, a camera equipped in a vehicle including a back view monitoring camera equipped in a vehicle, and a television camera), a scanner, a facsimile machine, a camera-equipped cell phone device, and a personal digital assistant (PDA).

Therefore, according to Embodiment 5 of the present invention, the color image signal from the solid-state image capturing apparatus 91 can be displayed on a display screen finely; printed out on a sheet of paper using an image output section 95; communicated finely as communication data via a wire or a radio; stored finely at the memory section 92 by performing predetermined data compression processing; and various data processes can be finely performed.

Although not specifically described in Embodiments 1 to 4 described above, the objective of the present invention to simplify the manufacturing steps can be achieved as long as the reflection preventing film provided above the light receiving section and the gate sidewall film of the transistor are formed with a common nitride film that is formed simultaneously.

As described above, the present invention is exemplified by the use of its preferred Embodiments 1 to 5. However, the present invention should not be interpreted solely based on Embodiments 1 to 5 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 5 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a solid-state image capturing element configured with a semiconductor element for performing a photoelectric conversion on and capturing an image light from a subject, a method for manufacturing the solid-state image capturing element, and an electronic information device, such as a digital camera (e.g., a digital video camera and a digital still camera), an image input camera (e.g., a security camera and a car-mounted camera), a scanner, a facsimile machine, and a camera-equipped cell phone device, having the solid-state image capturing element as an image input device used in an image capturing section thereof. The silicon nitride film is conventionally formed in two steps in the conventional semiconductor apparatus having both a light receiving section and a peripheral circuit, such as a CMOS solid-state image capturing element, because the necessary film thickness is different for a silicon nitride film that functions as a reflection preventing film above a light receiving section and a silicon nitride film that is used as a gate side wall film for a peripheral circuit of the light receiving section. On the other hand, according to the present invention as described above, the reflection preventing film provided above the light receiving section and the gate sidewall film of a peripheral circuit of the light receiving section are formed with a common silicon nitride film that is formed simultaneously, so that one step of forming the silicon nitride film forms both of the reflection preventing film and the gate sidewall film, thereby simplifying the manufacturing steps.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. A method for manufacturing a solid-state image capturing element in which one or plurality of light receiving sections for photoelectrically converting an incident light to generate a signal charge is provided on a surface of a semiconductor area or a surface of a semiconductor substrate and a peripheral circuit with a transistor is provided; the method comprising
a reflection preventing film and sidewall film forming step of forming a gate sidewall film of the transistor and a reflection preventing film provided above the light receiving sections in this order using a common nitride film that is formed simultaneously.

13. A method for manufacturing a solid-state image capturing element according to claim 12, wherein the reflection preventing film and sidewall film forming step includes:
a nitride film forming step of forming a nitride film above an area of the one or plurality of light receiving sections and the peripheral circuit;
a sidewall film forming step of forming a gate sidewall film of a transistor of the peripheral circuit, by masking the one or plurality of light receiving sections or each of the plurality of light receiving sections; and
a reflection preventing film forming step of forming the nitride film into a predetermined thickness as the reflection preventing film, by using a mask with an opening only above the light receiving section.

14. A method for manufacturing a solid-state image capturing element according to claim 12, wherein the reflection preventing film and sidewall film forming step includes:
a first nitride film forming step of forming a first nitride film above an area of the one or plurality of light receiving sections and the peripheral circuit;
a first sidewall film forming step of forming a first gate sidewall film of a transistor of the peripheral circuit, by masking the one or plurality of light receiving sections or each of the plurality of light receiving sections;
a second nitride film forming step of forming a second nitride film above the area of the one or plurality of light receiving sections and the peripheral circuit;
a second sidewall film forming step of forming a second gate sidewall film of the transistor of the peripheral circuit above the first gate sidewall film from the second nitride film, by masking the one or plurality of light receiving sections or each of the plurality of light receiving sections; and
a reflection preventing film forming step of forming the first nitride film and the second nitride film into a predetermined thickness as the reflection preventing film, by using a mask with an opening only above the light receiving section.

15. A method for manufacturing a solid-state image capturing element according to claim 12, wherein the reflection preventing film and sidewall film forming step includes:
a first nitride film forming step of forming a first nitride film above an area of the one or plurality of light receiving sections and the peripheral circuit;
a second nitride film forming step of forming a second nitride film above the first nitride film;
a sidewall film forming step of forming a gate sidewall film of a transistor of the peripheral circuit from the first nitride film and the second nitride film, by masking the one or plurality of light receiving sections or each of the plurality of light receiving sections; and
a reflection preventing film forming step of forming the first nitride film and the second nitride film into a predetermined thickness as the reflection preventing film, by using a mask with an opening only above the light receiving section.

16. A method for manufacturing a solid-state image capturing element according to claim 13, wherein the reflection preventing film is one layer of a silicon nitride film that is provided above the light receiving sections with a silicon oxide layer interposed therebetween.

17. A method for manufacturing a solid-state image capturing element according to claim 14, wherein the reflection preventing film has a two layered structure of a silicon nitride film functioning as the first nitride film provided above the light receiving sections with a silicon oxide layer interposed therebetween and a SiON film above the silicon nitride film functioning as the second nitride film.

18. A method for manufacturing a solid-state image capturing element according to claim 15, wherein the reflection preventing film has a two layered structure of a silicon nitride film functioning as the first nitride film provided above the light receiving sections with a silicon oxide layer interposed therebetween and a SiON film above the silicon nitride film functioning as the second nitride film.

19. A method for manufacturing a solid-state image capturing element according to claim 14, wherein the reflection preventing film has a two layered structure of a silicon nitride film having a low concentration of nitride, which functions as the first nitride film provided above the light receiving sections with a silicon oxide layer interposed therebetween, and a silicon nitride film having a high concentration of nitride, which functions as the second nitride film, above the silicon nitride film having a low concentration of nitride.

20. A method for manufacturing a solid-state image capturing element according to claim 15, wherein the reflection preventing film has a two layered structure of a silicon nitride film having a low concentration of nitride, which functions as the first nitride film provided above the light receiving sections with a silicon oxide layer interposed therebetween, and a silicon nitride film having a high concentration of nitride, which functions as the second nitride film, above the silicon nitride film having a low concentration of nitride.

21. A method for manufacturing a solid-state image capturing element according to any of claim 12, wherein the reflection preventing film and the sidewall film are respectively formed by an etching process.

22. (canceled)
